(19) United States
(12) Patent Application Publication
(10) Pub. No.: US 2025/0105135 A1
(43) Pub. Date: Mar. 27, 2025

(54) CORRUGATED CAPACITOR

(71) Applicant: TEXAS INSTRUMENTS INCORPORATED, Dallas, TX (US)

(72) Inventors: Jonas Höhenberger, Kissing (DE); Michael Hans Enzelberger-Heim, Munich (DE)

(21) Appl. No.: 18/472,837

(22) Filed: Sep. 22, 2023

(51) Int. Cl. H01L 23/522; H01L 27/06

(52) U.S. Cl. CPC H01L 23/5223; H10D 84/811; H10D 88/00

(57) ABSTRACT

The present disclosure generally relates to a corrugated capacitor in an integrated circuit (IC). In an example, an IC includes a first corrugated conductive layer, a second corrugated conductive layer, and a corrugated dielectric layer. The first corrugated conductive layer and the second corrugated conductive layer are over a semiconductor substrate. The corrugated dielectric layer is between the first corrugated conductive layer and the second corrugated conductive layer. Various examples may achieve a larger surface areas for respective plates of a capacitor for a given lateral footprint of the capacitor.

### BACKGROUND

Capacitors have a broad range of applications, such as uses in integrated circuits in combination with other components. Capacitors that are to implement large capacitances occupy large areas on a die. This increases the die area and/or may require each die to be larger thereby reducing the number of dies that can be fabricated from a single wafer.

### SUMMARY

This summary is provided to introduce a brief selection of disclosed concepts in a simplified form that are further described below in the detailed description including the drawings provided. Various disclosed devices and methods may be beneficially applied in the context of semiconductor processing in which a capacitor may be fabricated in an integrated circuit (IC). Some examples described herein may be applied to manufacturing a capacitor stack for a corrugated capacitor in an IC. While such examples may be expected to achieve a larger surface area of capacitor plates relative to a lateral footprint of the capacitor, no particular result is a requirement unless explicitly recited in a particular claim.

An example described herein is an IC. The IC includes first and second corrugated conductive layers and a corrugated dielectric layer. The first and second corrugated conductive layers are over a semiconductor substrate. The corrugated dielectric layer is between the first and second corrugated conductive layers.

Another example described herein is an IC. The IC includes a parallel plate capacitor over a semiconductor substrate. The parallel plate capacitor includes a first corrugated conductive layer, a second corrugated conductive layer, and a corrugated dielectric layer. The first corrugated conductive layer and the second corrugated conductive layer are over the semiconductor substrate. The corrugated dielectric layer is between the first corrugated conductive layer and the second corrugated conductive layer.

A further example described herein is a method of manufacturing an IC. A corrugated dielectric structure is formed over a semiconductor substrate. A first conductive layer is conformally formed over the corrugated dielectric structure. The first conductive layer includes a corrugated upper surface. A dielectric layer is conformally formed over the first conductive layer. A second conductive layer is conformally formed over the dielectric layer.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features may be understood in detail, reference is made to the following detailed description taken in conjunction with the accompanying drawings.

FIG. 1 is a cross-sectional view of an integrated circuit (IC) including a corrugated capacitor according to some examples.

FIG. 2 is a cross-sectional view of an IC including a corrugated capacitor according to some examples.

FIG. 3 is a cross-sectional view of an IC including a corrugated capacitor according to some examples.

FIGS. 4, 5, and 6 are respective layout views of surfaces of a corrugated capacitor according to some examples.

FIGS. 7, 8, 9, 10, 11, 12, 13, and 14 are cross sectional views of the IC of FIG. 1 during respective stages of manufacturing according to some examples.

FIGS. 15, 16, 17, 18, 19, 20, and 21 are cross sectional views of the IC of FIG. 3 during respective stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and may be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to a corrugated capacitor in an integrated circuit (IC). In some examples, an IC includes a corrugated dielectric structure over a semiconductor substrate. A first conductive layer is conformally over the corrugated dielectric structure. A dielectric layer is conformally over the first conductive layer. A second conductive layer is conformally over the dielectric layer. Various examples may achieve a larger surface areas for respective plates of a capacitor for a given lateral footprint of the capacitor. The larger surface area may result in a larger capacitance of the capacitor that may be achieved for the given lateral footprint. Other benefits or advantages may be achieved by various examples.

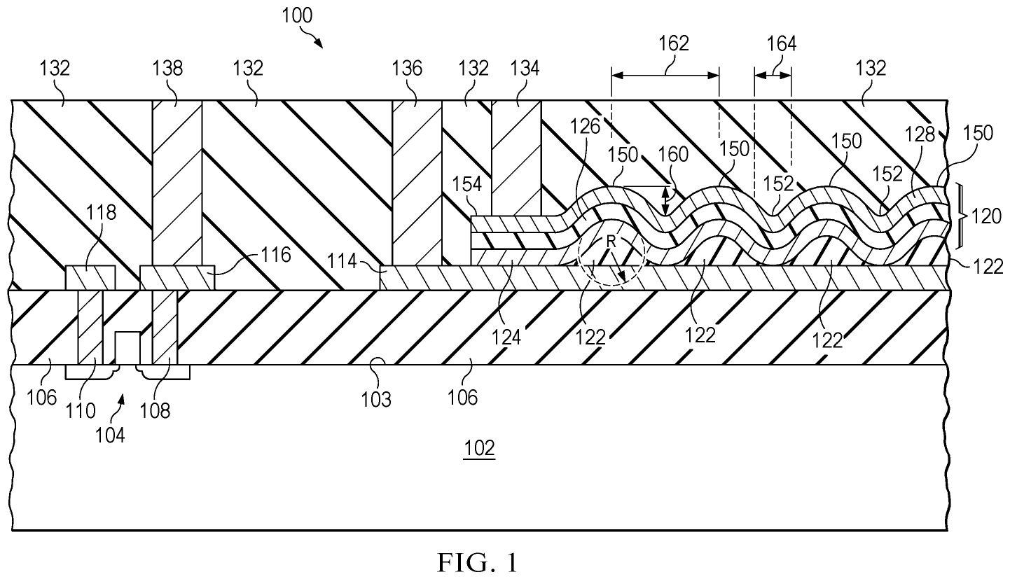

FIG. 1 is a cross-sectional view of an IC 100 including a capacitor according to some examples. The capacitor in the IC 100 is or includes a corrugated capacitor. Generally, a corrugated capacitor may have an effective capacitor area (e.g., from which a capacitance value is derived) that is greater than a lateral footprint of the corrugated capacitor.

The IC 100 include a semiconductor substrate 102 with a top surface 103. The semiconductor substrate 102 may be or include a bulk wafer, a semiconductor-on-insulator (SOI) substrate, or the like. The semiconductor substrate 102 may be or include any semiconductor material and may include a bulk material (e.g., bulk silicon) and/or one or more epitaxial layers of a semiconductor material. The IC 100 may include one or more active devices (e.g., transistor 104) formed in, on, and/or over the top surface 103 of the semiconductor substrate 102.

A first interconnect dielectric layer 106 is over the semiconductor substrate 102. The first interconnect dielectric layer 106 may be a pre-metal dielectric (PMD), an interlayer dielectric (ILD), an intermetal dielectric (IMD), or the like. The first interconnect dielectric layer 106 may include a conformal dielectric layer (e.g., an etch stop layer) over (e.g., possibly, on) the top surface 103 of the semiconductor substrate 102 and active devices (e.g., transistor 104) and may include a dielectric layer over the conformal dielectric layer. In some examples, the conformal dielectric layer may be or include silicon nitride, silicon oxynitride, the like, or a combination thereof, and the dielectric layer may be or include silicon oxide (such as phosphosilicate glass (PSG) or a tetraethyl orthosilicate (TEOS) oxide), the like, or a combination thereof.

Conductive contacts 108, 110 are through the first interconnect dielectric layer 106. The conductive contacts 108, 110 contact active regions of the transistor 104 in the semiconductor substrate 102. For example, the conductive contact 108 may contact a source region of the transistor 104 in the semiconductor substrate 102, and the conductive contact 110 may contact a drain region of the transistor 104 in the semiconductor substrate 102. The conductive contacts 108, 110 may each include one or more barrier and/or adhesion layers (e.g., titanium nitride (TiN), tantalum nitride (TaN), the like, or a combination thereof) conformally in a respective opening through the first interconnect dielectric layer 106, and a fill metal (e.g., tungsten (W), copper (Cu), aluminum (Al), the like, or a combination thereof) over and/or on the barrier and/or adhesion layer(s).

A conductive layer 114 and conductive lines 116, 118 are over the first interconnect dielectric layer 106. The conductive line 116 is over and contacts the conductive contact 108, and the conductive line 118 is over and contacts the conductive contact 110. The conductive layer 114 and conductive lines 116, 118, in some examples, are in an interconnect metal layer of an interconnect structure of the IC 100. The conductive layer 114 and conductive lines 116, 118 may each include one or more barrier and/or adhesion layers (e.g., titanium nitride (TiN), tantalum nitride (TaN), the like, or a combination thereof) over the first interconnect dielectric layer 106, and a fill metal (e.g., tungsten (W), copper (Cu), aluminum (Al), the like, or a combination thereof) over and/or on the barrier and/or adhesion layer(s).

A corrugated dielectric structure 122 is over at least a portion of the conductive layer 114. The conductive layer 114 extends laterally from the corrugated dielectric structure 122. The corrugated dielectric structure 122 has an upper surface that is corrugated with peaks and troughs. The upper surface of the corrugated dielectric structure 122 is distal from the conductive layer 114. In some examples, the upper surface of the corrugated dielectric structure 122 is periodic along the peaks and troughs along a lateral direction (e.g., one lateral direction or two lateral directions). More particularly, as illustrated in the cross-section of FIG. 1, the upper surface of the corrugated dielectric structure 122 has a curvilinear shape or follows a curvilinear wave function, e.g. resembling or following a sinusoidal wave function, along a lateral direction. The upper surface of the corrugated dielectric structure 122 may be discontinuous (e.g., at troughs), and/or the corrugated dielectric structure 122 may have one or more openings therethrough to the conductive layer 114. In some examples, the corrugated dielectric structure 122 may be or include silicon oxide (e.g., PSG or a TEOS oxide), silicon nitride, silicon oxynitride, the like, or a combination thereof.

A capacitor stack is over the corrugated dielectric structure 122 (e.g., over the upper surface of the corrugated dielectric structure 122). The capacitor stack includes a lower capacitor conductive layer 124 over the corrugated dielectric structure 122, a capacitor dielectric layer 126 over the lower capacitor conductive layer 124, and an upper capacitor conductive layer 128 over the capacitor dielectric layer 126. The lower capacitor conductive layer 124 is conformally over and on the upper surface of the corrugated dielectric structure 122. The capacitor dielectric layer 126 is conformally over and on an upper surface of the lower capacitor conductive layer 124, and the upper capacitor conductive layer 128 is conformally over and on an upper surface of the capacitor dielectric layer 126. The conformal nature of the capacitor conductive layers 124, 128 and capacitor dielectric layer 126 results, generally, in the corrugated structure of the corrugated dielectric structure 122 being propagated through the capacitor conductive layers 124, 128 and capacitor dielectric layer 126. Each of the capacitor conductive layers 124, 128 and capacitor dielectric layer 126 has a respective upper surface, at least a portion of which generally replicates the upper surface of the corrugated dielectric structure 122, which may result, for example, in the respective upper surfaces being periodic and/or having a curvilinear shape or follows a curvilinear wave function, e.g. resembling or following a sinusoidal wave function, along a lateral direction in some examples.

The respective upper surfaces of the capacitor conductive layers 124, 128 and capacitor dielectric layer 126 have peaks 150 and troughs 152 that correspond to the peaks and troughs of the upper surface of the corrugated dielectric structure 122. Hence, the capacitor conductive layers 124, 128 and capacitor dielectric layer 126 may each have a corrugated structure and a corrugated upper surface and may form, at least in part, a corrugated capacitor 120. The upper surfaces of the capacitor conductive layers 124, 128 and capacitor dielectric layer 126 have a respective peak-to-trough height 160 (shown in FIG. 1 for the upper surface of the upper capacitor conductive layer 128). The peak-to-trough height 160 is a height from a trough 152 to a neighboring peak 150 of a given surface. In some examples, the peak-to-trough height 160 is at least 50 nm. The capacitor conductive layers 124, 128 and capacitor dielectric layer 126 may form a parallel plate or parallel film corrugated capacitor.

The corrugated capacitor 120 permits a larger capacitance based on an areal, lateral footprint of the corrugated capacitor 120 as compared to a planar capacitor having the same lateral footprint. “Lateral footprint” or “lateral area” refers to the area of the IC 100 parallel to the top surface 103 covered by the corrugated capacitor 120. The corrugated structure of the surfaces of the capacitor conductive layers 124, 128 have a greater surface area than the lateral footprint of the corrugated structure of the corrugated capacitor 120, which permits a greater capacitance to be achieved by the corrugated capacitor 120. In some examples, respective surface areas of the corrugated portions of the upper surface of the lower capacitor conductive layer 124 and the lower surface of the upper capacitor conductive layer 128 are at least one and a half times larger (e.g., at least two or three times larger) than the lateral footprint area of the respective corrugated portions of those surfaces in which those corrugated portions are disposed.

In the illustrated example, the corrugated capacitor 120 is periodic. A period 162 of the corrugated capacitor 120 is shown between neighboring peaks 150 of the corrugated capacitor 120 (e.g., between corresponding peaks 150 of the upper surfaces of the capacitor conductive layers 124, 128 and capacitor dielectric layer 126). Along a lateral direction parallel to the top surface 103, the upper surface of the lower capacitor conductive layer 124, throughout a period (e.g., the period 162) between neighboring peaks 150, may have a radius of curvature R not less than 500 nm, may exclude bends with a radius of curvature less than 500 nm, and/or may have a minimum radius of curvature of 500 nm. The lower surface of the upper capacitor conductive layer 128 may also have similar characteristics. In such examples, such geometry may be beneficial to the reliability of the corrugated capacitor 120. Having too small of a radius of curvature (e.g., such as a sharp corner making an angle >85°) of the surfaces of the capacitor conductive layers 124, 128 could otherwise result in a large electric field at such points, which could result in shorter time dependent dielectric breakdown (TDDB).

Additionally, a smaller period 162 and/or increased peak-to-trough height 160 may increase surface area of the upper surface of the lower capacitor conductive layer 124 and the lower surface of the upper capacitor conductive layer 128 to increase capacitance. FIG. 1 shows a full-width half-max (FWHM) 164, which is a width between an upper surface of the upper capacitor conductive layer 128 (as illustrated) or the lower capacitor conductive layer 124 at a height from the trough 152 (or peak 150) that is half of the peak-to-trough height 160. According to some examples, a ratio of the peak-to-trough height 160 to the FWHM 164 is at least 10%. Increasing this ratio may result in a smaller period and/or increased peak-to-trough height to increase capacitance of the corrugated capacitor 120.

In the illustrated example, the upper surface of the corrugated dielectric structure 122 is discontinuous at troughs such that the lower capacitor conductive layer 124 contacts the conductive layer 114 at the troughs. Additionally, the lower capacitor conductive layer 124 extends laterally beyond the corrugated dielectric structure 122 where the lower capacitor conductive layer 124 also is over and contacts the conductive layer 114. In the illustrated example, the lower capacitor conductive layer 124, the capacitor dielectric layer 126, and the upper capacitor conductive layer 128 are laterally co-extensive, and hence, the capacitor dielectric layer 126 and the upper capacitor conductive layer 128 also extend laterally beyond the corrugated dielectric structure 122. The respective portions 154 of the lower capacitor conductive layer 124, capacitor dielectric layer 126, and upper capacitor conductive layer 128 that laterally extend beyond the corrugated dielectric structure 122 are planar. The conductive layer 114 extends laterally beyond the capacitor conductive layers 124, 128 and capacitor dielectric layer 126. The conductive layer 114 may include a pad or plate underlying the capacitor conductive layers 124, 128 and capacitor dielectric layer 126 that extends at least laterally co-extensively or beyond the capacitor conductive layers 124, 128 and capacitor dielectric layer 126.

The capacitor conductive layers 124, 128 may be or include any appropriate conductive material, such as a metal (including a metal alloy), a doped semiconductor, a metal-semiconductor compound, the like, or a combination thereof. Examples include metals such as aluminum (Al), copper (Cu), tungsten (W), molybdenum (Mo), tantalum (Ta), alloys thereof, metal compounds such as titanium nitride (TiN) and tantalum nitride (TaN), or a combination thereof. Example doped semiconductor include doped silicon (e.g., doped polysilicon), doped silicon germanium, doped germanium, the like, or a combination thereof. Example metal-semiconductor compounds include silicides (e.g., NiSi, TiSi, etc.), germanides, or the like. The capacitor dielectric layer 126 may be or include silicon oxide, silicon nitride, hafnium oxide, the like, or a combination thereof.

A second interconnect dielectric layer 132 is over the conductive layer 114, conductive lines 116, 118, the capacitor stack, and the first interconnect dielectric layer 106. The second interconnect dielectric layer 132 may be an ILD, an IMD, or the like. The second interconnect dielectric layer 132 may include a conformal dielectric layer (e.g., an etch stop layer) over (e.g., possibly, on) the top surface of the first interconnect dielectric layer 106, sidewall surfaces and upper surfaces of the conductive layer 114, conductive lines 116, 118, and upper capacitor conductive layer 128, and sidewall surfaces of the lower capacitor conductive layer 124 and capacitor dielectric layer 126. The second interconnect dielectric layer 132 may further include a dielectric layer over the conformal dielectric layer. In some examples, the conformal dielectric layer may be or include silicon nitride, silicon oxynitride, the like, or a combination thereof, and the dielectric layer may be or include silicon oxide (such as PSG or a TEOS oxide), the like, or a combination thereof.

Conductive vias 134, 136, 138 extend through the second interconnect dielectric layer 132. The conductive via 134 extends through the second interconnect dielectric layer 132 to the upper capacitor conductive layer 128. The conductive via 136 extends through the second interconnect dielectric layer 132 to the conductive layer 114. The conductive via 138 extends through the second interconnect dielectric layer 132 to the conductive line 116. The corrugated capacitor 120 may be electrically connected to the transistor 104 through the conductive vias 136, 138 in an electrical circuit. An overlying interconnect metal layer may electrically connect the conductive vias 136, 138. The conductive vias 134, 136, 138 may each include one or more barrier and/or adhesion layers (e.g., titanium nitride (TiN), tantalum nitride (TaN), the like, or a combination thereof) conformally in a respective opening through the second interconnect dielectric layer 132, and a fill metal (e.g., tungsten (W), copper (Cu), aluminum (Al), the like, or a combination thereof) over and/or on the barrier and/or adhesion layer(s).

Additional interconnect dielectric layers and interconnect metal layers may be formed over the second interconnect dielectric layer 132. The first interconnect dielectric layer 106, second interconnect dielectric layer 132, additional dielectric layers, and interconnect metal layers therein may form an interconnect structure. Conductive lines in neighboring interconnect metal layers may be electrically coupled by vias, which may interconnect various devices, including the transistor 104 and the corrugated capacitor 120, in an electrical circuit. The corrugated capacitor 120 may be formed at any level of an interconnect structure in various examples. For example, any number of interconnect dielectric layers (with corresponding interconnect metal layers) may be between the semiconductor substrate 102 and the corrugated capacitor 120.

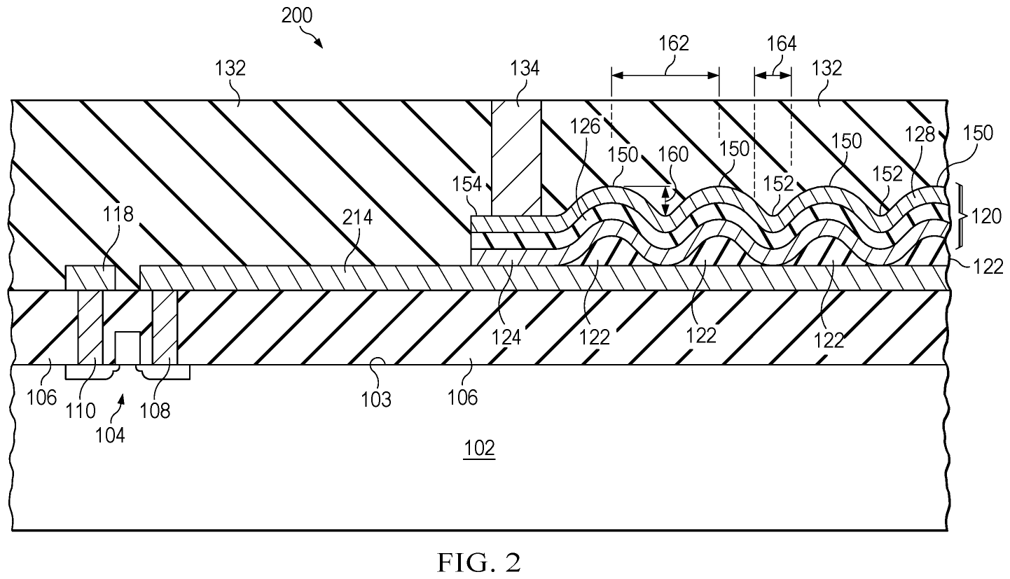

FIG. 2 is a cross-sectional view of an IC 200 including a capacitor according to some examples. The capacitor in the IC 200 is or includes the corrugated capacitor 120 like in FIG. 1. The IC 200 of FIG. 2 includes components included in the IC 100 of FIG. 1, which are indicated by like reference numbers. Description of such components is omitted for brevity.

The IC 200 includes a conductive layer 214 (similar to the conductive layer 114 of FIG. 1). The conductive layer 214 is over the first interconnect dielectric layer 106 and the conductive contact 108. The conductive layer 214, in some examples, is in an interconnect metal layer of an interconnect structure of the IC 200. The conductive layer 214 may include material(s) like described above with respect to the conductive layer 114.

The corrugated dielectric structure 122 is over a portion of the conductive layer 214. The conductive layer 214 extends laterally from the corrugated dielectric structure 122 to contact the conductive contact 108. In the illustrated example, the upper surface of the corrugated dielectric structure 122 is discontinuous at troughs such that the lower capacitor conductive layer 124 contacts the conductive layer 214 at the troughs. Additionally, the lower capacitor conductive layer 124 extends laterally beyond the corrugated dielectric structure 122 where the lower capacitor conductive layer 124 also is over and contacts the conductive layer 214. The conductive layer 214 extends laterally beyond the capacitor conductive layers 124, 128 and capacitor dielectric layer 126 to contact the conductive contact 108. The conductive layer 214 may include a pad or plate underlying the capacitor conductive layers 124, 128 and capacitor dielectric layer 126 that extends at least laterally co-extensively or beyond the capacitor conductive layers 124, 128 and capacitor dielectric layer 126. In the illustrated example of FIG. 2, the conductive layer 214 is directly connected to the via 108 thereby providing a conductive electrical connection to the transistor 104, which form at least in part an electrical circuit.

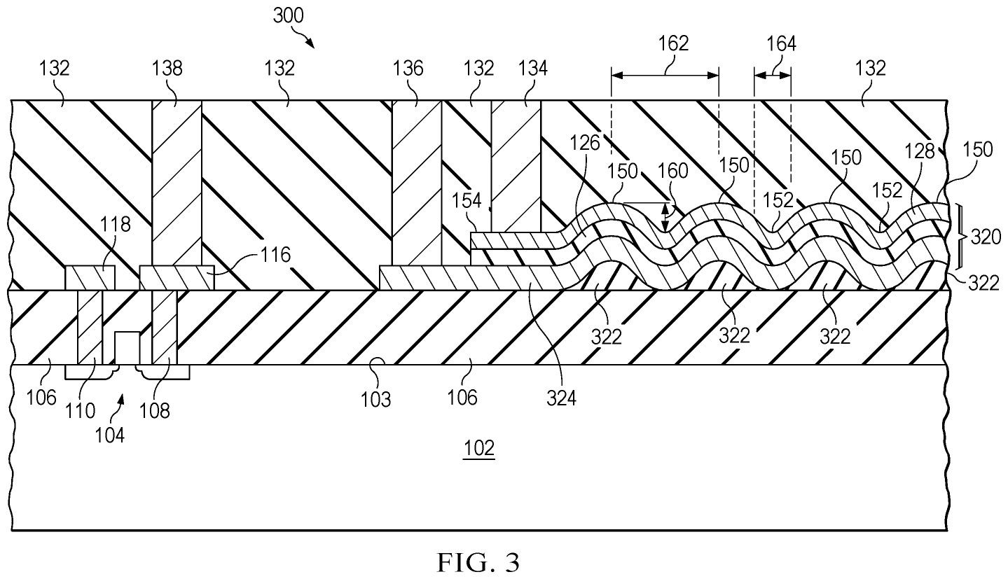

FIG. 3 is a cross-sectional view of an IC 300 including a capacitor 320 according to some examples. The capacitor in the IC 300 is or includes a corrugated capacitor 320 similar to the corrugated capacitor 120 in FIG. 1. The IC 300 of FIG. 3 includes components included in the IC 100 of FIG. 1, which are indicated by like reference numbers. Description of such components is omitted for brevity.

A corrugated dielectric structure 322 is over and on the first interconnect dielectric layer 106. The corrugated dielectric structure 322 may be like the corrugated dielectric structure 122 in FIG. 1. A conductive layer 324 is conformally over and on the upper surface of the corrugated dielectric structure 322 and extends laterally from the corrugated dielectric structure 322. The conductive layer 324, in some examples, is in an interconnect metal layer of an interconnect structure of the IC 100 that includes the conductive lines 116, 118. The conductive layer 324 may be or include the material(s) described above with respect to the conductive layer 114. In some examples, the conductive layer 324 may be over and contacting the conductive contact 108 (e.g., similar to the conductive layer 214 in FIG. 2). The capacitor dielectric layer 126 is conformally over and on the conductive layer 324, and the upper capacitor conductive layer 128 is conformally over and on the capacitor dielectric layer 126.

In the illustrated example, the capacitor dielectric layer 126 and the upper capacitor conductive layer 128 are laterally co-extensive, and the capacitor dielectric layer 126 and the upper capacitor conductive layer 128 extend laterally beyond the corrugated dielectric structure 322. The respective portions of the conductive layer 324, capacitor dielectric layer 126, and upper capacitor conductive layer 128 that laterally extend beyond the corrugated dielectric structure 322 are planar. The conductive layer 324 also extends laterally beyond the capacitor dielectric layer 126 and the upper capacitor conductive layer 128.

A capacitor stack, in the illustrated example, includes the conductive layer 324, capacitor dielectric layer 126, and upper capacitor conductive layer 128. The capacitor stack is over the corrugated dielectric structure 322 (e.g., over the upper surface of the corrugated dielectric structure 322).

A second interconnect dielectric layer 132 is over the conductive layer 324, the conductive lines 116, 118, the capacitor stack, and the first interconnect dielectric layer 106. Conductive vias 134, 136, 138 extend through the second interconnect dielectric layer 132. The conductive via 136 extends through the second interconnect dielectric layer 132 to the conductive layer 324. The corrugated capacitor 320 may be electrically connected to the transistor 104 through the conductive vias 136, 138 in an electrical circuit in some examples. In some examples, the conductive layer 324 may be directly electrically connected to the conductive contact 108 to provide a conductive electrical connection to the transistor 104. Additional interconnect dielectric layers and interconnect metal layers may be formed over the second interconnect dielectric layer 132, which may form an interconnect structure. The corrugated capacitor 320 may be formed at any level of an interconnect structure in various examples.

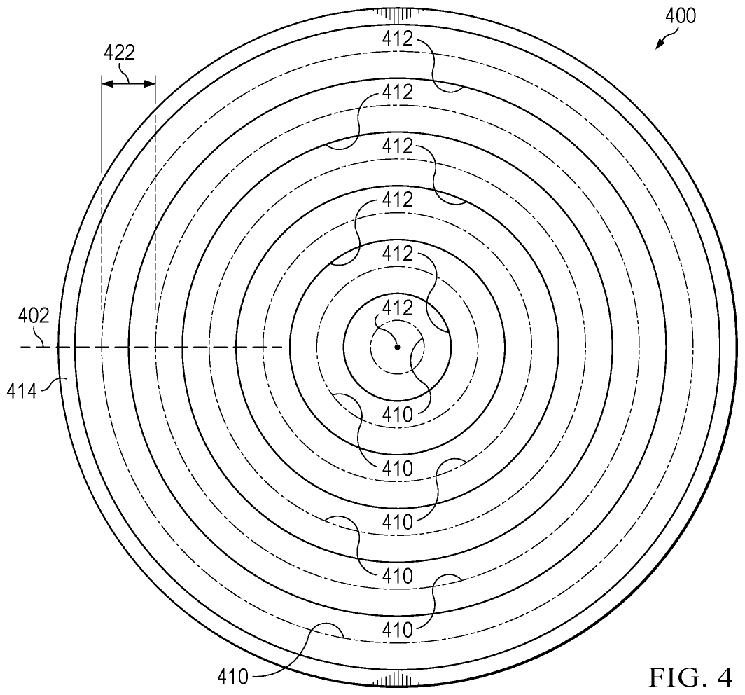

FIG. 4 is a layout view of a surface 400 of a corrugated capacitor according to some examples. The respective cross-sections of the corrugated capacitors in FIGS. 1, 2, and 3 may be along cross-section 402. The surface 400 may correspond to any or each of the upper or lower surfaces of the lower capacitor conductive layer 124, the conductive layer 324, the capacitor dielectric layer 126, and the upper capacitor conductive layer 128. Additionally, the surface 400 may correspond to the upper surface of the corrugated dielectric structure 122, 322.

The surface 400 has peaks 410 and troughs 412, which may correspond to peaks 150 and troughs 152, respectively. The peaks 410 and troughs 412 radiate laterally outwardly from a center much like a ripple. The surface 400 has a period 422 between neighboring peaks 410 (or neighboring troughs 412), which may correspond to the period 162. Around a periphery, the surface 400 has a planar portion 414, which may correspond to the planar portion 154. As shown by the surface 400 of FIG. 4, a corrugated capacitor may be periodic in two lateral directions. The period 422 may be along any lateral radial direction from a center of the surface 400.

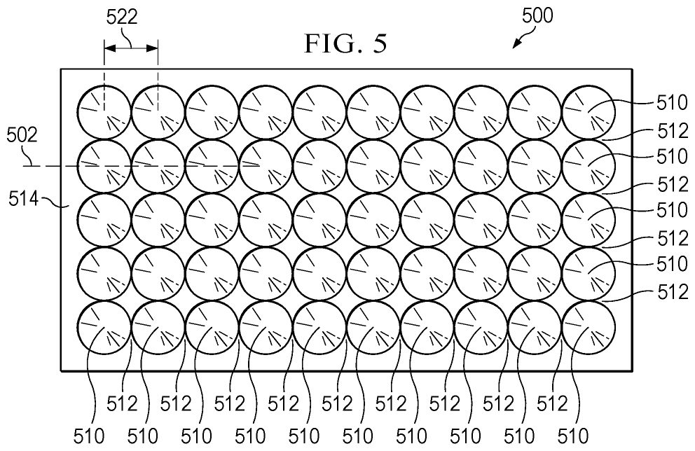

FIG. 5 is a layout view of a surface 500 of a corrugated capacitor according to some examples. The respective cross-sections of the corrugated capacitors in FIGS. 1, 2, and 3 may be along cross-section 502. The surface 500 may correspond to any or each of the upper or lower surfaces of the lower capacitor conductive layer 124, the conductive layer 324, the capacitor dielectric layer 126, and the upper capacitor conductive layer 128. Additionally, the surface 500 may correspond to the upper surface of the corrugated dielectric structure 122, 322.

The surface 500 has peaks 510 and troughs 512, which may correspond to peaks 150 and troughs 152, respectively. The peaks 510 may form or be individual mounds, where the peaks 410 form a lateral array. The surface 500 has a period 522 between neighboring peaks 510 (or neighboring troughs 512), which may correspond to the period 162. Around a periphery, the surface 500 has a planar portion 514, which may correspond to the planar portion 154. As shown by the surface 500 of FIG. 5, a corrugated capacitor may be periodic in two lateral directions. The period 522 may be along two or more lateral directions.

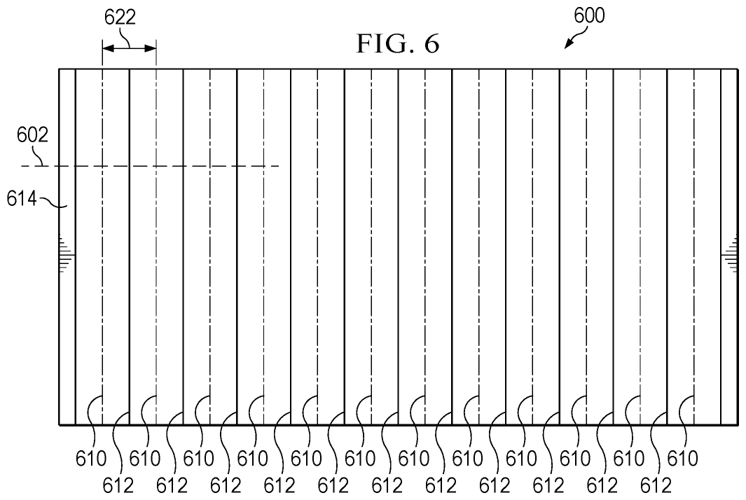

FIG. 6 is a layout view of a surface 600 of a corrugated capacitor according to some examples. The respective cross-sections of the corrugated capacitors in FIGS. 1, 2, and 3 may be along cross-section 602. The surface 600 may correspond to any or each of the upper or lower surfaces of the lower capacitor conductive layer 124, the conductive layer 324, the capacitor dielectric layer 126, and the upper capacitor conductive layer 128. Additionally, the surface 600 may correspond to the upper surface of the corrugated dielectric structure 122, 322.

The surface 600 has peaks 610 and troughs 612, which may correspond to peaks 150 and troughs 152, respectively. The surface 600 has a period 622 between neighboring peaks 610 (or neighboring troughs 612), which may correspond to the period 162. At a periphery, the surface 600 has a planar portion 614, which may correspond to the planar portion 154. As shown by the surface 600 of FIG. 6, a corrugated capacitor may be periodic in one lateral directions.

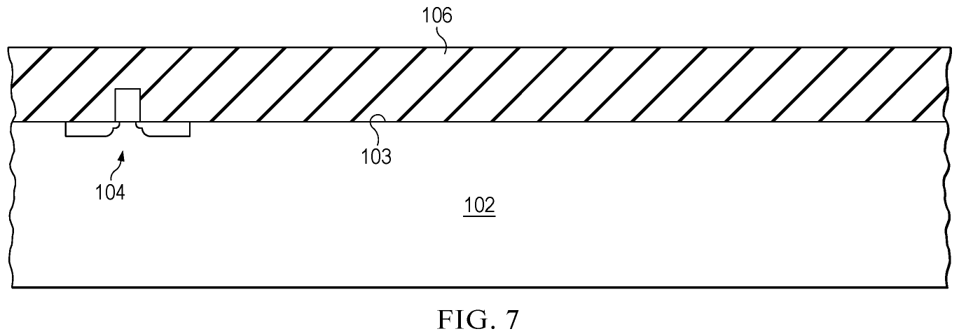

FIGS. 7 through 14 are cross sectional views of the IC 100 of FIG. 1 during respective stages of a method of manufacturing according to some examples. Although illustrated in the context of manufacturing the IC 100 of FIG. 1, the method may be implemented to manufacture the IC 200 of FIG. 2 as described subsequently.

Referring to FIG. 7, the semiconductor substrate 102 is provided. The semiconductor substrate 102 includes one or more active devices (e.g., transistor 104) formed in, on, and/or over the top surface 103 of the semiconductor substrate 102. The active device(s) may be formed using any appropriate front-end-of-the-line (FEOL) processing. The first interconnect dielectric layer 106 is formed over and on the semiconductor substrate 102. The first interconnect dielectric layer 106 may be or include any material described above with respect to the first interconnect dielectric layer 106 and may be deposited by chemical vapor deposition (CVD), plasma enhanced CVD (PECVD), low pressure CVD (LPCVD), or any other deposition process. The first interconnect dielectric layer 106 may have a planar top surface, such as by planarizing the first interconnect dielectric layer 106 by a chemical mechanical polish (CMP).

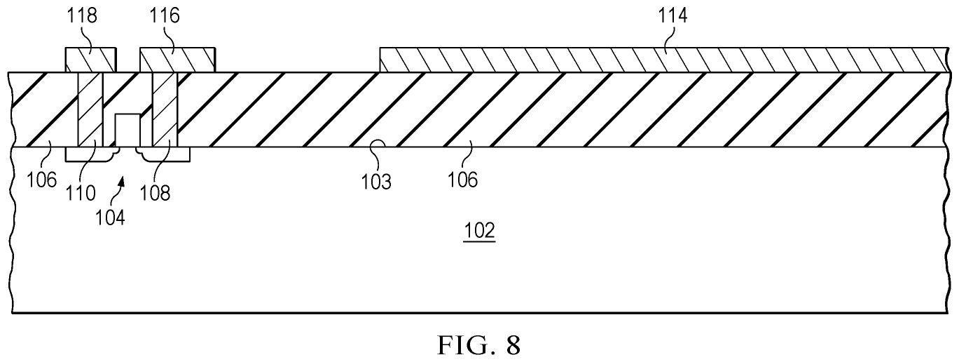

Referring to FIG. 8, the conductive contacts 108, 110, conductive layer 114, and conductive lines 116, 118 are formed. Openings may be formed through the first interconnect dielectric layer 106 to, e.g., the semiconductor substrate 102 using appropriate photolithography and etching processes. A metal(s) of the conductive contacts 108, 110, conductive layer 114, and conductive lines 116, 118 are deposited in the openings and over and on the first interconnect dielectric layer 106. The metal(s) may be deposited using an appropriate deposition process(es), such as CVD, physical vapor deposition (PVD), or the like. The metal(s) over the first interconnect dielectric layer 106 are patterned using appropriate photolithography and etching processes into the conductive layer 114 and conductive lines 116, 118. In examples to manufacture the IC 200 of FIG. 2, the metal(s) over the first interconnect dielectric layer 106 are patterned into the conductive layer 214 and conductive line 118.

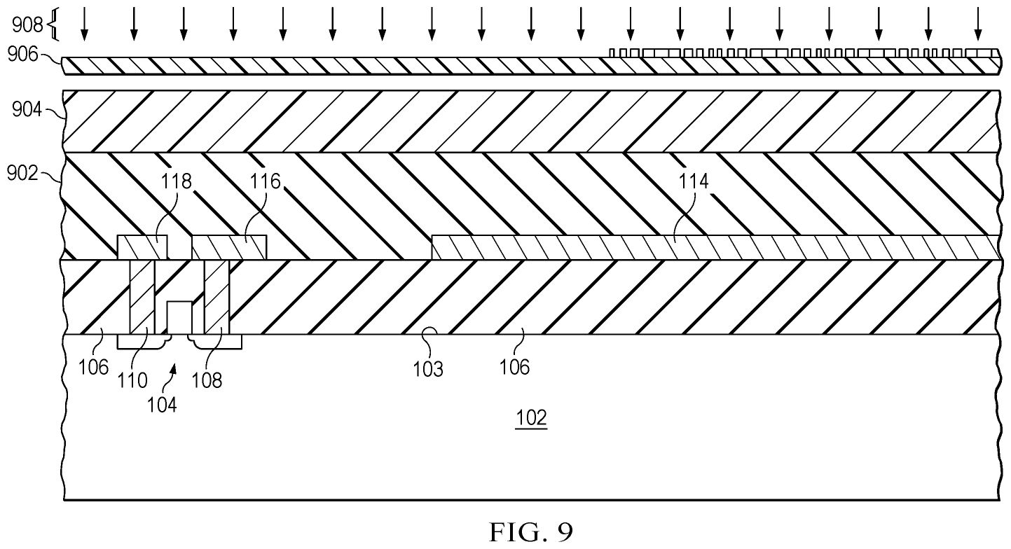

Referring to FIG. 9, an intermediate dielectric layer 902 is formed over and on the first interconnect dielectric layer 106, the conductive layer 114, and the conductive lines 116, 118 (or conductive layer 214 and conductive line 118). As described subsequently, the intermediate dielectric layer 902 is to be patterned into the corrugated dielectric structure 122. The intermediate dielectric layer 902 may be or include any material described above for the corrugated dielectric structure 122 and may be deposited by CVD, PECVD, LPCVD, or any other deposition process.

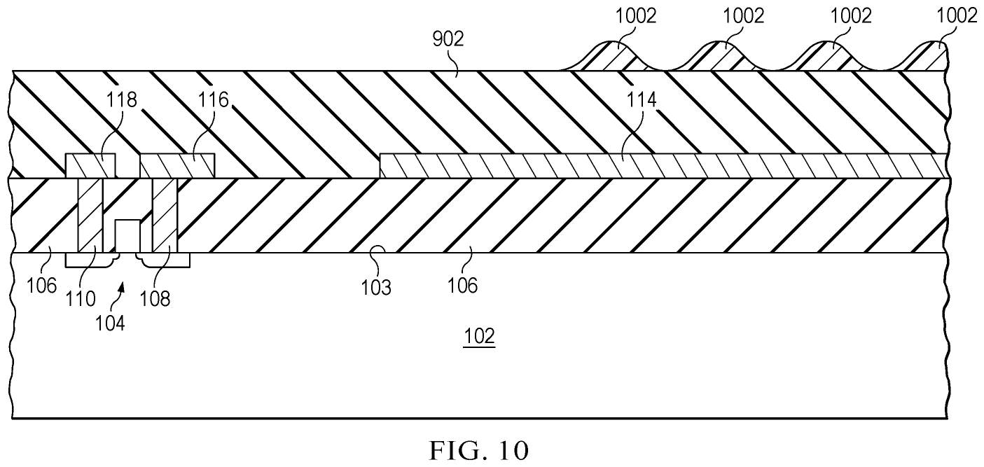

A photoresist 904 is deposited over and on the intermediate dielectric layer 902. The photoresist 904 may be deposited using spin-on or another appropriate deposition technique. Then, the photoresist 904 is patterned using grayscale photolithography. The grayscale photolithography, as illustrated in FIG. 9, uses a grayscale lithography mask 906 and transmits electromagnetic radiation 908 (e.g., light) through the grayscale lithography mask 906 to expose the photoresist 904 to the pattern of the grayscale lithography mask 906. As shown in FIG. 10, the photoresist 904 is patterned into a patterned photoresist 1002 by the grayscale photolithography after developing and curing the photoresist 904 after exposure. The patterned photoresist 1002 corresponds in lateral location and three-dimensional shape to the corrugated dielectric structure 122 to be formed. In examples, any appropriate grayscale photolithography technique may be implemented. For example, an i-line grayscale photolithography technique may be implemented. In other examples, a KrF grayscale technique may be implemented. In other examples, a maskless digital grayscale photolithography technique may be implemented.

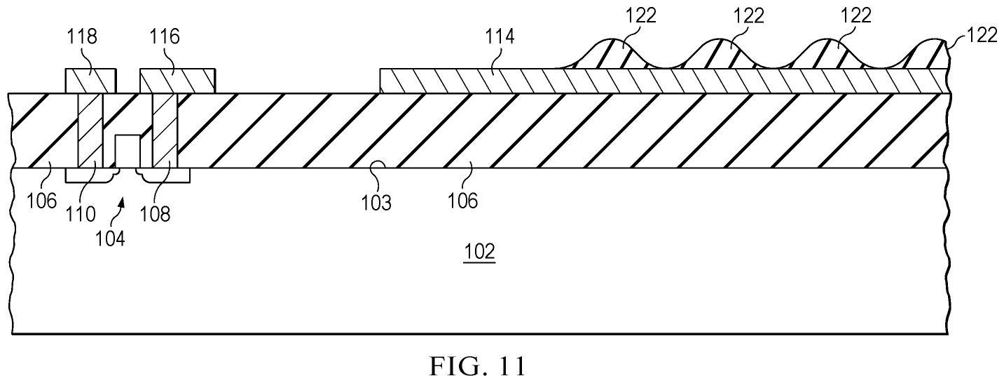

Referring to FIG. 11, the corrugated dielectric structure 122 is formed from the intermediate dielectric layer 902. Using the patterned photoresist 1002 as a mask, the intermediate dielectric layer 902 is etched to transfer the pattern of the patterned photoresist 1002 to the intermediate dielectric layer 902 to thereby form the corrugated dielectric structure 122. The etch may be anisotropic and may etch or consume both the patterned photoresist 1002 and the intermediate dielectric layer 902. In some examples, an etch rate of the intermediate dielectric layer 902 is approximately equal to the etch rate of the patterned photoresist 1002.

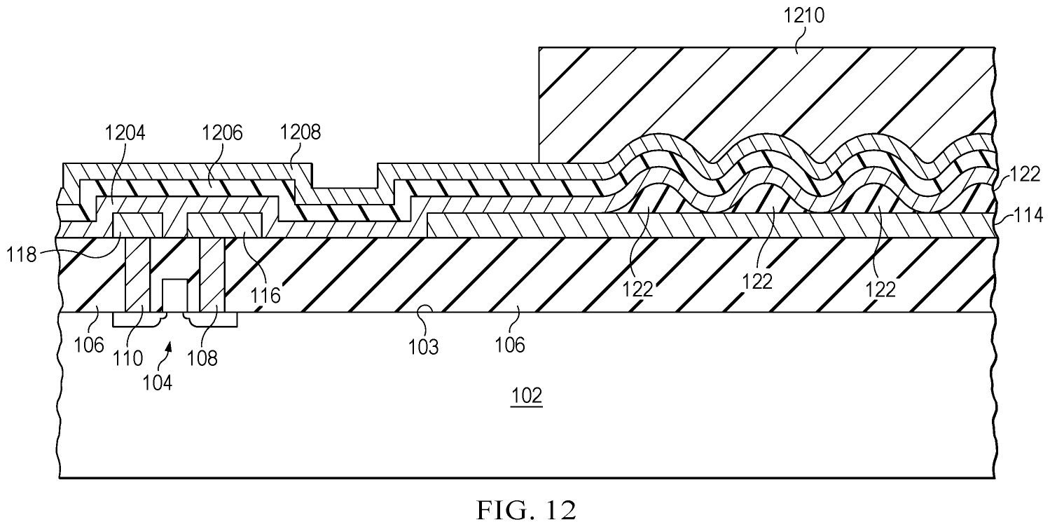

Referring to FIG. 12, blanket capacitor conductive layers 1204, 1208 and a blanket capacitor dielectric layer 1206 are formed. The blanket lower capacitor conductive layer 1204 is deposited conformally over and on the upper surface of the corrugated dielectric structure 122, the upper and sidewall surfaces of the conductive layer 114 and conductive lines 116, 118, and the upper surface of the first interconnect dielectric layer 106. The blanket capacitor dielectric layer 1206 is deposited conformally over and on the upper surface of the blanket lower capacitor conductive layer 1204, and the blanket upper capacitor conductive layer 1208 is deposited conformally over and on the upper surface of the blanket capacitor dielectric layer 1206. The blanket capacitor conductive layers 1204, 1208 and blanket capacitor dielectric layer 1206 may be any of the materials as described above for the capacitor conductive layers 124, 128 and capacitor dielectric layer 126, respectively, and may be deposited using PECVD, atomic layer deposition (ALD), or the like.

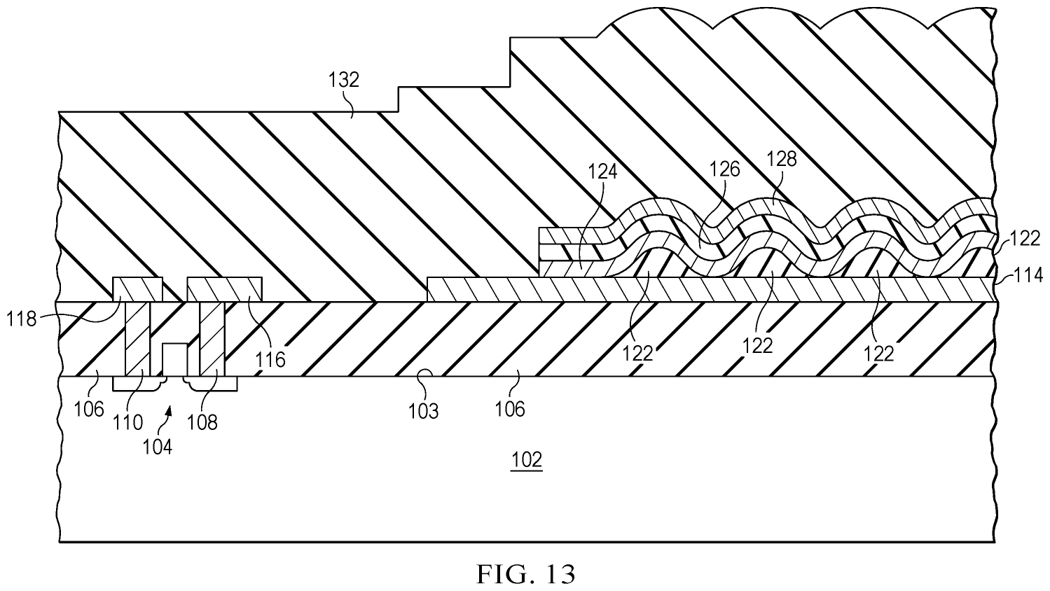

The blanket capacitor conductive layers 1204, 1208 and blanket capacitor dielectric layer 1206 are patterned into the capacitor conductive layers 124, 128 and the capacitor dielectric layer 126, respectively. The patterning may be by using appropriate photolithography and etching processes. For example, a photoresist 1210 is deposited (e.g., by spin-on) over the blanket upper capacitor conductive layer 1208 and patterned corresponding to the lateral footprint of the corrugate capacitor using photolithography. Using the photoresist 1210 as a mask, the blanket capacitor conductive layers 1204, 1208 and blanket capacitor dielectric layer 1206 are etched to pattern the blanket capacitor conductive layers 1204, 1208 and blanket capacitor dielectric layer 1206 into the capacitor conductive layers 124, 128 and the capacitor dielectric layer 126, as shown in FIG. 13. Any remaining photoresist 1210 is removed, such as by ashing.

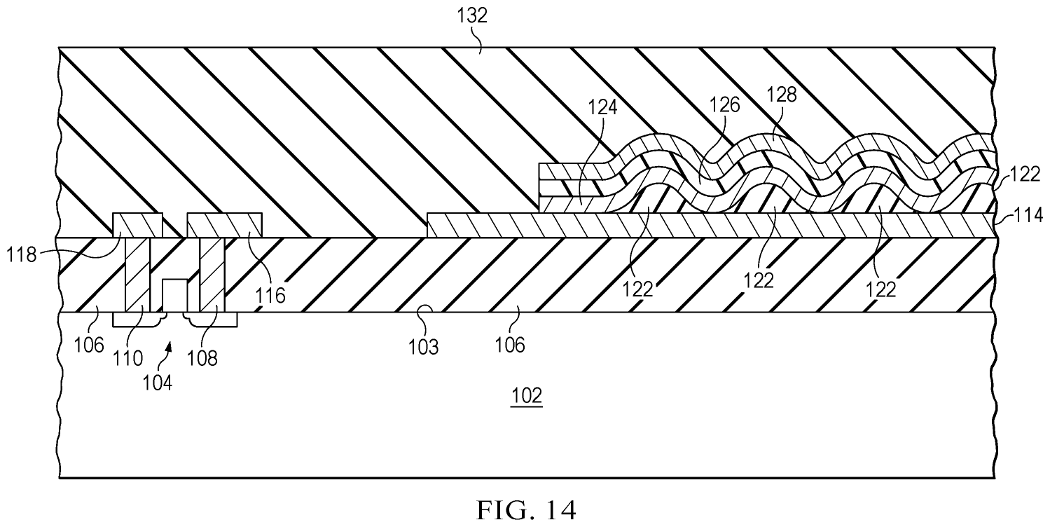

Further referring to FIG. 13, the second interconnect dielectric layer 132 is formed over and on the first interconnect dielectric layer 106, the conductive layer 114, the conductive lines 116, 118, and the upper capacitor conductive layer 128. The second interconnect dielectric layer 132 may be or include any material as described above for the second interconnect dielectric layer 132 and may be deposited by CVD, PECVD, LPCVD, or any other deposition process. Upon being deposited, an upper surface of the second interconnect dielectric layer 132 may have a topography approximating or corresponding to the topography of the conductive layer 114, the conductive lines 116, 118, and the corrugated capacitor 120. The topography of the second interconnect dielectric layer 132 may be removed, and the second interconnect dielectric layer 132 may be planarized, by a CMP, as shown in FIG. 14.

Referring to FIG. 1, the conductive vias 134, 136, 138 are formed. Using appropriate photolithography and etching processes, respective openings may be formed through the second interconnect dielectric layer 132 to the conductive layer 114, the conductive line 116 and the upper capacitor conductive layer 128. A metal(s) of the conductive vias 134, 136, 138 are deposited in the openings. The metal(s), such as described above, may be deposited using an appropriate deposition process(es), such as CVD, PVD, or the like.

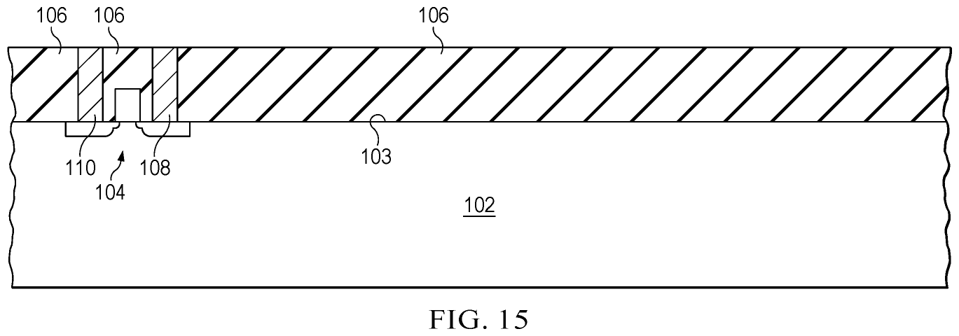

FIGS. 15 through 21 are cross sectional views of the IC 300 of FIG. 3 during respective stages of a method of manufacturing according to some examples. Like in FIG. 7, the semiconductor substrate 102 is provided. The first interconnect dielectric layer 106 is formed over and on the semiconductor substrate 102.

Referring to FIG. 15, the conductive contacts 108, 110 are formed. Openings may be formed through the first interconnect dielectric layer 106 to, e.g., the semiconductor substrate 102 using appropriate photolithography and etching processes. A metal(s) of the conductive contacts 108, 110 are deposited in the openings. The metal(s) may be deposited using an appropriate deposition process(es), such as CVD, PVD, or the like. Any excess metal(s) over the first interconnect dielectric layer 106 may be removed by a CMP.

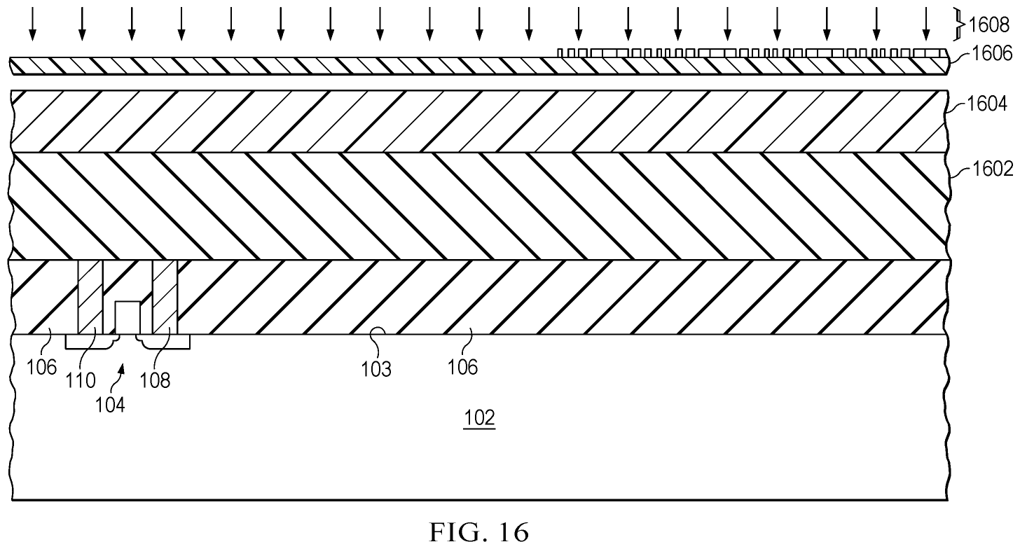

Referring to FIG. 16, an intermediate dielectric layer 1602 is formed over and on the first interconnect dielectric layer 106. As described subsequently, the intermediate dielectric layer 1602 is to be patterned into the corrugated dielectric structure 322. The intermediate dielectric layer 1602 may be or include any material described above for the corrugated dielectric structure 322 and may be deposited by CVD, PECVD, LPCVD, or any other deposition process.

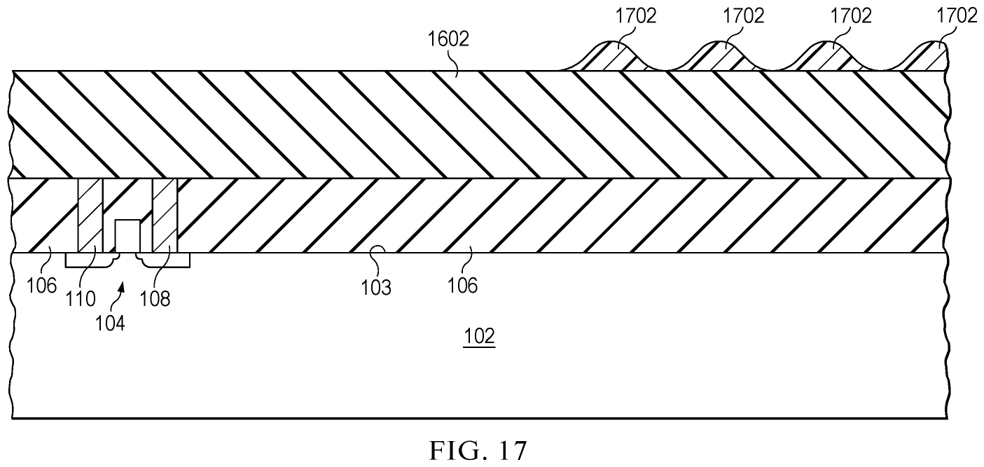

A photoresist 1604 is deposited over and on the intermediate dielectric layer 1602. The photoresist 1604 may be deposited using spin-on or another appropriate deposition technique. Then, the photoresist 1604 is patterned using grayscale photolithography. The grayscale photolithography, as illustrated in FIG. 16, uses a grayscale lithography mask 1606 and transmits electromagnetic radiation 1608 (e.g., light) through the grayscale lithography mask 1606 to expose the photoresist 1604 to the pattern of the grayscale lithography mask 1606. As shown in FIG. 17, the photoresist 1604 is patterned into a patterned photoresist 1702 by the grayscale photolithography after developing and curing the photoresist 1604 after exposure. The patterned photoresist 1702 corresponds in lateral location and three-dimensional shape to the corrugated dielectric structure 322 to be formed. In examples, any appropriate grayscale photolithography technique may be implemented. For example, an i-line grayscale photolithography technique may be implemented. In other examples, a KrF grayscale technique may be implemented. In other examples, a maskless digital grayscale photolithography technique may be implemented.

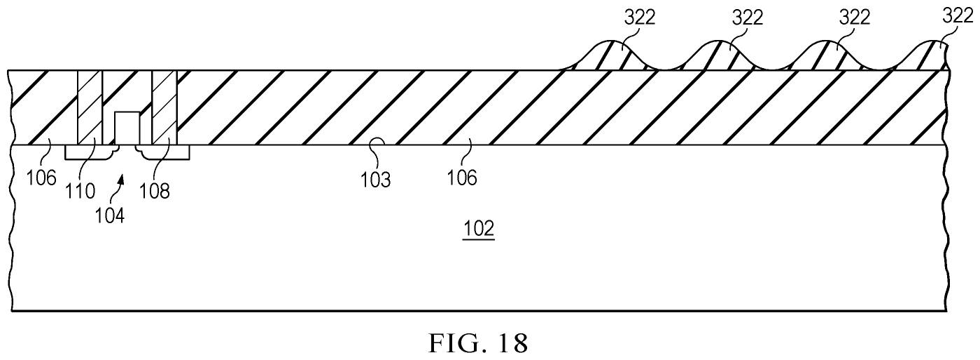

Referring to FIG. 18, the corrugated dielectric structure 322 is formed from the intermediate dielectric layer 1602. Using the patterned photoresist 1702 as a mask, the intermediate dielectric layer 1602 is etched to transfer the pattern of the patterned photoresist 1702 to the intermediate dielectric layer 1602 to thereby form the corrugated dielectric structure 322. The etch may be anisotropic and may etch or consume both the patterned photoresist 1702 and the intermediate dielectric layer 1602. In some examples, an etch rate of the intermediate dielectric layer 1602 is approximately equal to the etch rate of the patterned photoresist 1702.

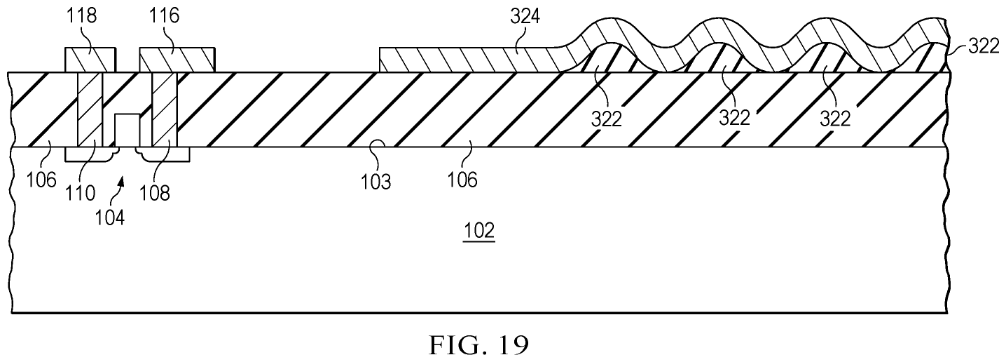

Referring to FIG. 19, the conductive layer 324 and conductive lines 116, 118 are formed. A metal(s) of the conductive layer 324 and conductive lines 116, 118 are deposited conformally over and on the first interconnect dielectric layer 106 and the corrugated dielectric structure 322. The metal(s) may be deposited using an appropriate deposition process(es), such as CVD, ALD, or the like. The metal(s) over the first interconnect dielectric layer 106 and the corrugated dielectric structure 322 are patterned using appropriate photolithography and etching processes into the conductive layer 324 and conductive lines 116, 118. In some examples, the metal(s) may be patterned such that the conductive layer 324 extends to contacting the conductive contact 108.

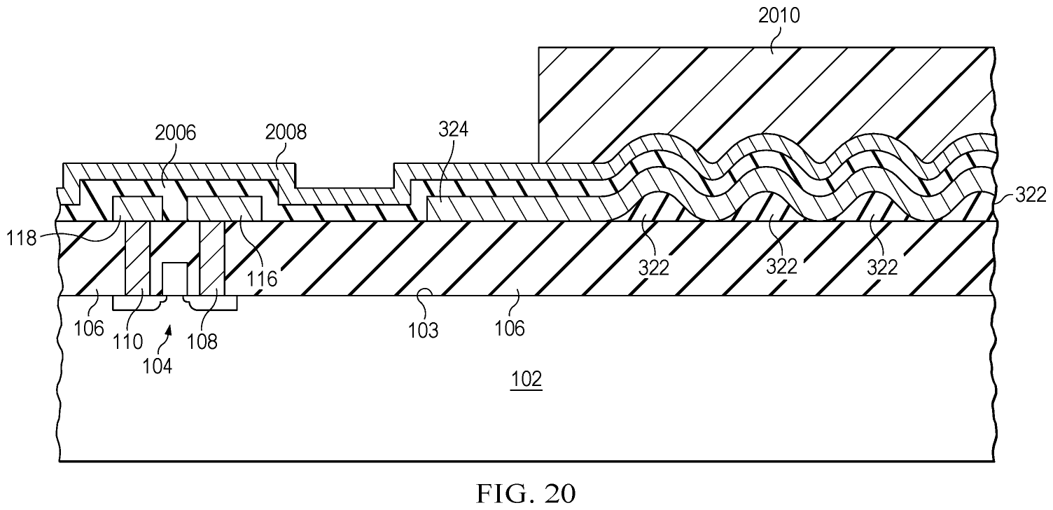

Referring to FIG. 20, a blanket capacitor dielectric layer 2006 and a blanket upper capacitor conductive layer 2008 are formed. The blanket capacitor dielectric layer 2006 is deposited conformally over and on the upper and sidewall surfaces of the conductive layer 324 and conductive lines 116, 118 and the upper surface of the first interconnect dielectric layer 106. The blanket upper capacitor conductive layer 2008 is deposited conformally over and on the upper surface of the blanket capacitor dielectric layer 2006. The blanket capacitor dielectric layer 2006 and the blanket upper capacitor conductive layer 2008 may be any of the materials as described above for the capacitor dielectric layer 126 and the upper capacitor conductive layer 128 and, respectively, and may be deposited using PECVD, ALD, or the like.

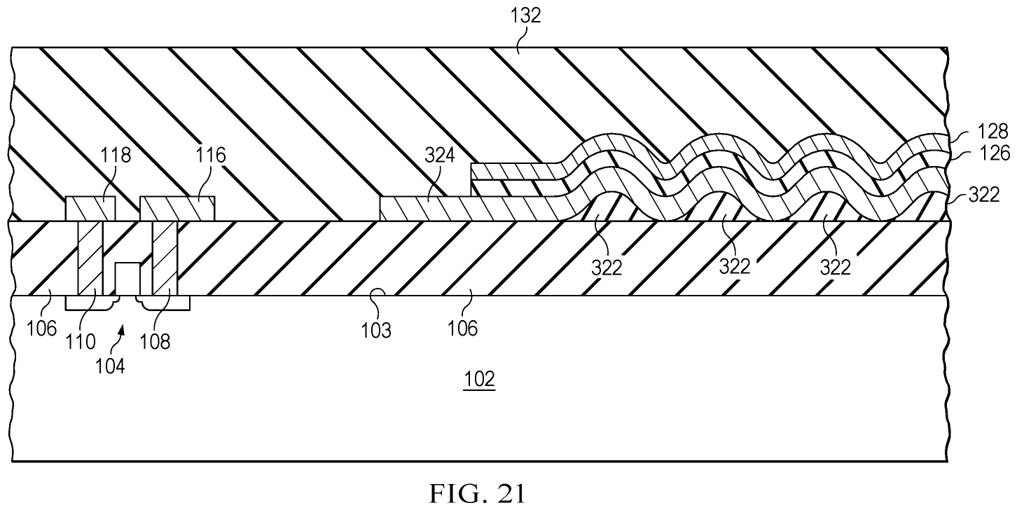

The blanket capacitor dielectric layer 2006 and the blanket upper capacitor conductive layer 2008 are patterned into the capacitor dielectric layer 126 and the upper capacitor conductive layer 128, respectively. The patterning may be by using appropriate photolithography and etching processes. For example, a photoresist 2010 is deposited (e.g., by spin-on) over the blanket upper capacitor conductive layer 2008 and patterned corresponding to the lateral footprint of the corrugate capacitor using photolithography. Using the photoresist 2010 as a mask, the blanket upper capacitor conductive layer 2008 and blanket capacitor dielectric layer 2006 are etched to pattern the blanket upper capacitor conductive layer 2008 and blanket capacitor dielectric layer 2006 into the upper capacitor conductive layer 128 and the capacitor dielectric layer 126, as shown in FIG. 21. Any remaining photoresist 2010 is removed, such as by ashing.

Further referring to FIG. 21, the second interconnect dielectric layer 132 is formed over and on the first interconnect dielectric layer 106, the conductive layer 324, the conductive lines 116, 118, and the upper capacitor conductive layer 128, like described with respect to FIGS. 13 and 14. Referring to FIG. 3, the conductive vias 134, 136, 138 are formed, like described with respect to FIG. 1.

Although various examples have been described in detail, it should be understood that various changes, substitutions, and alterations may be made therein without departing from the scope defined by the appended claims.

What is claimed is:

1. An integrated circuit (IC) comprising:
first and second corrugated conductive layers over a semiconductor substrate; and
a corrugated dielectric layer between the first and second corrugated conductive layers.

2. The IC of claim 1, further comprising a corrugated dielectric structure between the semiconductor substrate and the first corrugated conductive layer, the corrugated dielectric structure having a first surface on a planar top surface of the semiconductor substrate and a second surface touching the first corrugated conductive layer.

3. The IC of claim 2, further comprising a third conductive layer between the semiconductor substrate and the first corrugated conductive layer, the first corrugated conductive layer contacting the third conductive layer through a trough of the corrugated dielectric structure.

4. The IC of claim 3, further comprising:
an interconnect dielectric layer over the third conductive layer and the second corrugated conductive layer;
a first conductive via through the interconnect dielectric layer to the third conductive layer; and
a second conductive via through the interconnect dielectric layer to the second corrugated conductive layer.

5. The IC of claim 1, wherein the first corrugated conductive layer has a corrugated upper surface, the corrugated dielectric layer being over the corrugated upper surface, and wherein, in a lateral direction, the corrugated upper surface follows a sinusoidal wave function.

6. The IC of claim 1, wherein the first corrugated conductive layer has a corrugated upper surface, the corrugated dielectric layer being over the corrugated upper surface, and wherein, along a lateral direction from a peak to a neighboring peak, the corrugated upper surface has no radius of curvature less than 500 nm.

7. The IC of claim 1, wherein the first corrugated conductive layer has a corrugated upper surface, the corrugated dielectric layer being over the corrugated upper surface, and wherein a surface area of the corrugated upper surface is at least one and a half times larger than a lateral footprint of the corrugated upper surface.

8. The IC of claim 1, wherein the first corrugated conductive layer has a corrugated upper surface, the corrugated dielectric layer being over the corrugated upper surface, and wherein the corrugated upper surface has a peak and a trough neighboring the peak, a height from the peak to the trough is at least 50 nm.

9. The IC of claim 1, wherein:
the first corrugated conductive layer has a corrugated upper surface, the corrugated dielectric layer being over the corrugated upper surface;
the corrugated upper surface has a first peak, a trough, and a second peak, the second peak neighboring the first peak, the trough being between the first peak and the second peak;
a height is from the trough to the first peak;
a width is between the corrugated upper surface between the first peak and the second peak at half the height from the trough; and
a ratio of the height to the width is at least 10%.

10. The IC of claim 1, further comprising a transistor, wherein the first corrugated conductive layer, the corrugated dielectric layer, and the second corrugated conductive layer form a capacitor, the transistor being connected to the capacitor in an electrical circuit.

11. The IC of claim 10, wherein the first corrugated conductive layer is implemented by an interconnect metal layer that provides a conductive connection to the transistor.

12. The IC of claim 1, wherein the corrugated dielectric layer comprises silicon oxide, silicon nitride, hafnium oxide, or a combination thereof.

13. An integrated circuit (IC) comprising:
a parallel plate capacitor over a semiconductor substrate, the parallel plate capacitor comprising:
a first corrugated conductive layer and a second corrugated conductive layer over the semiconductor substrate; and
a corrugated dielectric layer between the first corrugated conductive layer and the second corrugated conductive layer.

14. The IC of claim 13, further comprising
a third conductive layer over the semiconductor substrate; and
a corrugated dielectric structure over the third conductive layer, the corrugated dielectric structure having a corrugated upper surface, the first corrugated conductive layer being over the corrugated upper surface of the corrugated dielectric structure, the first corrugated conductive layer contacting the third conductive layer through a trough of the corrugated upper surface of the corrugated dielectric structure.

15. The IC of claim 14, further comprising:
an interconnect dielectric layer over the third conductive layer and the second corrugated conductive layer;
a first conductive via through the interconnect dielectric layer to the third conductive layer; and
a second conductive via through the interconnect dielectric layer to the second corrugated conductive layer.

16. The IC of claim 13, wherein, along a lateral direction, an upper surface of the first corrugated conductive layer follows a sinusoidal wave shape.

17. The IC of claim 13, wherein, along a lateral direction from a first peak through a trough to a second peak, an upper surface of the first corrugated conductive layer does not include a bend with a radius of curvature less than 500 nm.

18. The IC of claim 13, wherein a surface area of an upper surface of the first corrugated conductive layer is at least one and a half times larger than a lateral area in which the surface area of the upper surface of the first corrugated conductive layer is disposed.

19. A method of manufacturing an integrated circuit (IC), the method comprising:
forming a corrugated dielectric structure over a semiconductor substrate;
forming a first conductive layer conformally over the corrugated dielectric structure, the first conductive layer including a corrugated upper surface;
forming a dielectric layer conformally over the first conductive layer; and
forming a second conductive layer conformally over the dielectric layer.

20. The method of claim 19, wherein forming the corrugated dielectric structure includes:
depositing an intermediate dielectric layer over the semiconductor substrate;
forming a photoresist over the intermediate dielectric layer including patterning the photoresist using grayscale lithography; and
etching the intermediate dielectric layer into the corrugated dielectric structure using the patterned photoresist as a mask.
